(19) United States
(12) Patent Application Publication
(10) Pub. No.: US 2023/0137996 A1
(43) Pub. Date: May 4, 2023

(54) CONDUCTIVE MEMBERS WITH UNOBSTRUCTED INTERFACIAL AREA FOR DIE ATTACH IN FLIP CHIP PACKAGES

(71) Applicant: TEXAS INSTRUMENTS INCORPORATED, Dallas, TX (US)

(72) Inventors: Christlyn Faith Arias, Taguig City (PH); Rafael Jose Guevara, Metro Manila (PH)

(21) Appl. No.: 17/514,984

(22) Filed: Oct. 29, 2021

(51) Int. Cl. H01L 23/00

(52) U.S. Cl. CPC H01L 24/13; H01L 24/16; H01L 24/11; H01L 24/81; H01L 24/73; H01L 24/95; H01L 2224/16245; H01L 2224/11849; H01L 2224/11622; H01L 2224/81815; H01L 2224/73204; H01L 2224/13147; H01L 2224/13019; H01L 2224/13564; H01L 2224/1357

(57) ABSTRACT

A semiconductor package includes a semiconductor die having a device side, a conductive layer coupled to the device side, a conductive pillar coupled to the conductive layer, the conductive pillar having an upper portion and a base portion, the upper portion having a wider diameter than the base portion and the conductive pillar either having a mushroom shape or having sloped sides on the base portion extending away from the upper portion to the conductive layer, a polyimide layer coupled to the conductive layer and surrounding the conductive pillar, a solder layer coupled to the conductive pillar, wherein the polyimide layer does not extend between a top surface of the conductive pillar and the solder layer, and a conductive terminal coupled to the solder layer and exposed to a surface of the semiconductor package, the device side of the semiconductor die facing the conductive terminal.

### BACKGROUND

Flip-chip packaging is a method for interconnecting semiconductor devices, such as integrated circuit (IC) dies and micro-electromechanical systems (MEMS), to external circuitry using solder bumps that have been deposited onto die pads. The solder bumps are deposited on die pads on the top side of a semiconductor wafer during wafer processing. In order to mount the chip to external circuitry, such as a circuit board or another chip, the wafer is flipped over so that its top side faces down. The upside-down wafer is then aligned so that conductive pads on the wafer align with matching pads on the external circuit or lead frame. Solder on the bumps is reflowed to complete the interconnect between the devices. The bumps are conductive members that electrically and mechanically couple device areas of the dies through metal redistribution layers, polyimide layers, passivation layers, die pads, etc.

### SUMMARY

A semiconductor package includes a semiconductor die having a device side, a conductive layer coupled to the device side, a conductive pillar coupled to the conductive layer, the conductive pillar having an upper portion and a base portion, the upper portion having a wider diameter than the base portion and the conductive pillar having a mushroom shape, a polyimide layer coupled to the conductive layer and surrounding the conductive pillar, a solder layer coupled to the conductive pillar, wherein the polyimide layer does not extend between a top surface of the conductive pillar and the solder layer, and a conductive terminal, such as a lead frame, coupled to the solder layer and exposed to a surface of the semiconductor package, the device side of the semiconductor die facing the conductive terminal.

A semiconductor package includes a semiconductor die having a device side, a conductive layer coupled to the device side, a conductive pillar coupled to the conductive layer, the conductive pillar having an upper portion and a base portion, the base portion having a wider diameter than the upper portion, wherein the base portion of the conductive pillar has sloped sides extending from the upper portion to the conductive layer, a polyimide layer coupled to the conductive layer and surrounding the conductive pillar, a solder layer coupled to the conductive pillar, wherein the polyimide layer does not extend between a top surface of the conductive pillar and the solder layer, and a conductive terminal coupled to the solder layer and exposed to a surface of the semiconductor package, the device side of the semiconductor die facing the conductive terminal.

A method of manufacturing a semiconductor package includes providing a semiconductor wafer having a device side, forming a conductive layer above the device side, forming a conductive pillar above the conductive layer, the conductive pillar having a base portion and an upper portion, wherein one of the base or upper portions is wider than the other portion such that the conductive pillar has a mushroom shape or the base portion has sloped sides extending from the upper portion to the conductive layer, forming a polyimide layer abutting the conductive layer and surrounding the conductive pillar, positioning a conductive member on the conductive pillar, wherein the polyimide layer does not extend between a top surface of the conductive pillar and the conductive member, reflowing the conductive member, singulating the semiconductor wafer to produce a die having the conductive layer, the conductive pillar, the polyimide layer, and the reflowed conductive member, coupling the reflowed conductive member to a conductive terminal using a reflow technique, thereby producing a solder layer coupling the conductive pillar to the conductive terminal, and covering the die, the conductive pillar, the solder layer, and the conductive terminal in a molding, the conductive terminal exposed to a surface of the molding.

### BRIEF DESCRIPTION OF THE DRAWINGS

Having thus described the invention in general terms, reference will now be made to the accompanying drawings, wherein:

FIG. 1 is a cross section view of a prior art flip chip with an exemplary solder joint.

FIG. 2 is a flow diagram of a method for forming pillar bumps having an unobstructed solder interfacial area according to an example embodiment.

FIGS. 3A-H are a series of cross-sectional views illustrating the steps in the formation of pillar bumps having a sloped top surface using the process of FIG. 2.

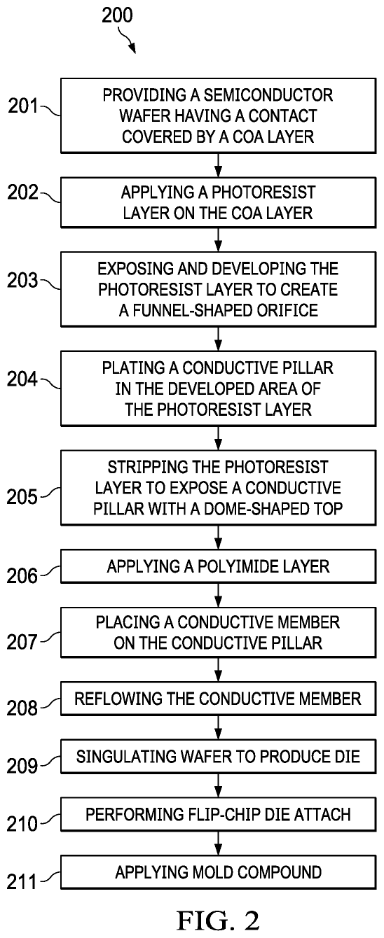

FIG. 2 is a flow diagram of a method for forming pillar bumps having an unobstructed solder interfacial area according to an example embodiment.

FIGS. 5A-H are a series of cross-sectional views illustrating the steps in the formation of pillar bumps having a footer portion using the process of FIG. 4.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In the drawings, like reference numerals refer to like elements throughout, and the various features are not necessarily drawn to scale. Corresponding numerals and symbols in the different figures generally refer to corresponding parts, unless otherwise indicated. In the following discussion and in the claims, the terms “including,” “includes,” “having,” “has,” “with,” or variants thereof are intended to be inclusive in a manner similar to the term “comprising”, and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

In flip chip packaging, products use a solder alloy to bond metallic pillars or posts, which are formed on a semiconductor die, to a lead frame. Typically, the posts are copper (Cu), and the lead frame is copper. In one example, manufacturing costs may be reduced by eliminating a typical sputter and etch process step and by applying a passivation layer, such as a polyimide (PI) layer, after creation of the posts. While a solder bond provides a good connection between the copper posts and a copper lead frame, there are potential solder-joint quality and reliability issues when a passivation layer is applied after creating the posts and not removed before solder is attached to the posts. For example, the PI layer may overlap the top of the post if a typical post design is used. This PI overlap can reduce the interfacial surface area between the solder and the post, for example, by covering an outer edge on the top surface of the post, thereby leaving a smaller area available on the top of the post for bonding to the solder. As used herein, the term interfacial region refers to an exposed area on one feature adapted for bonding to another feature. By reducing the interfacial surface area, the bond between the solder and the post may be subject to higher stress due to its smaller connection, which is detrimental to the package's lifespan and may reduce the electronic performance to the package.

An example process for producing a flip-chip device is disclosed herein. The process eliminates PI overlap by modifying the structure of the posts on the semiconductor wafer. In one configuration, a mushroom-like post is created by applying a resist thickness that is lower than a target post height. As used herein, the term mushroom-like refers to a structure having a columnar base with a wider circular top, such as an umbrella-shaped cap. In another configuration, a footing is created on the posts by modifying photoresist process parameters. The footing provides a wide base portion of the post. In one example, the footing has sloping sides that ramp downward from the post to a contact layer. These configurations create structures that prevent the PI layer from overlapping the post, which thereby prevents a reduction in interfacial surface area between the post and the solder.

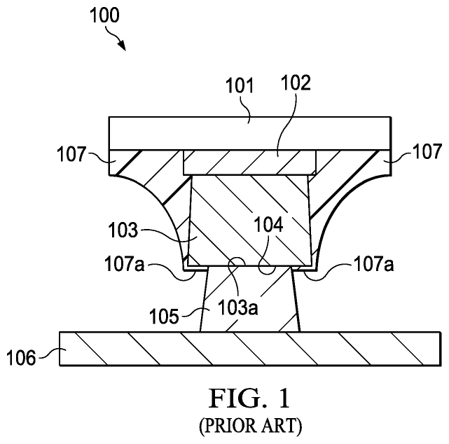

FIG. 1 is a cross section view of a prior art flip chip 100 with an exemplary solder joint. At each contact region of semiconductor die 101, a metal layer may be deposited and then patterned to form a metalized contact region 102. This region 102 is referred to as a “copper over anything” (COA) layer, A metallic post 103 is formed in contact with the metalized contact region 102. The post 103 has a top surface 103a that functions as the region for post 103 to bond to solder ball 105. Solder ball 105 may be placed on either the post 103 or on a lead frame 106 and then heated to form a solder bond between interfacial region 104 of post 103 and lead frame 106 using a Thermosonic or reflow process, for example.

Prior to applying the solder ball 105 to post 103, a PI passivation layer 107 is applied over semiconductor die 101 and contact area 102. The PI layer 107 also surrounds post 103 and, using existing designs, a portion 107a of the PI layer 103 typically overlaps at least a portion of top surface 103a on post 103. As a result, the interfacial region 104 between post 103 and solder ball 105 is less than the entire top surface 103a of post 103. The solder ball 105 forms a layer between post 103 and lead frame 106. Because the interfacial region 104 is narrower than the available post surface 103a, current capacity through post 103 to or from circuitry on die 101 may be limited. Furthermore, because the post-solder interface is narrower than otherwise possible, there may be a tendency for cracks to form between lead frame 106 and post 103, for example, due to thermal cycling.

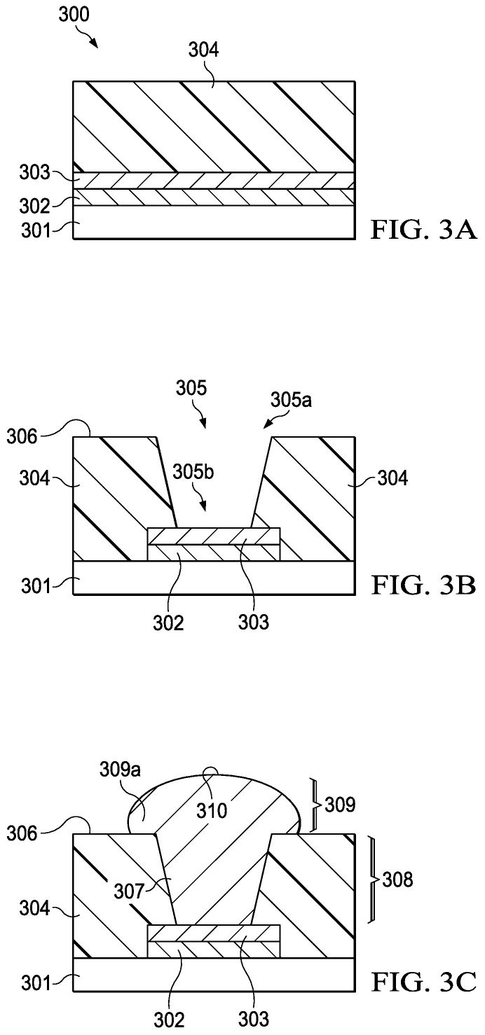

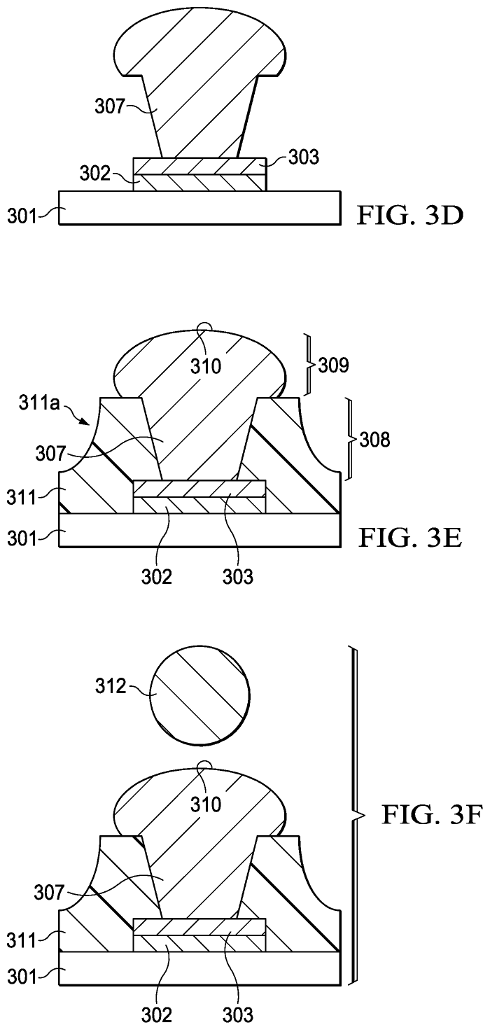

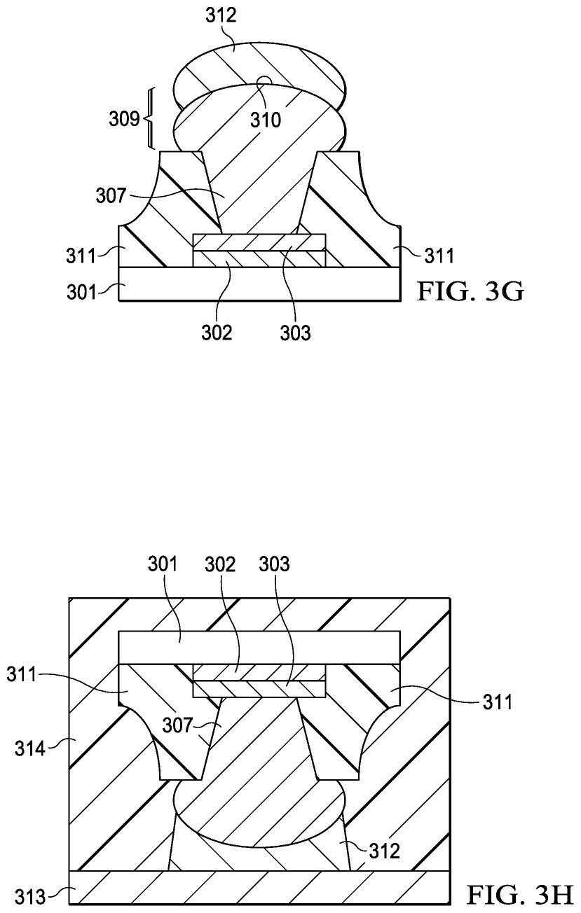

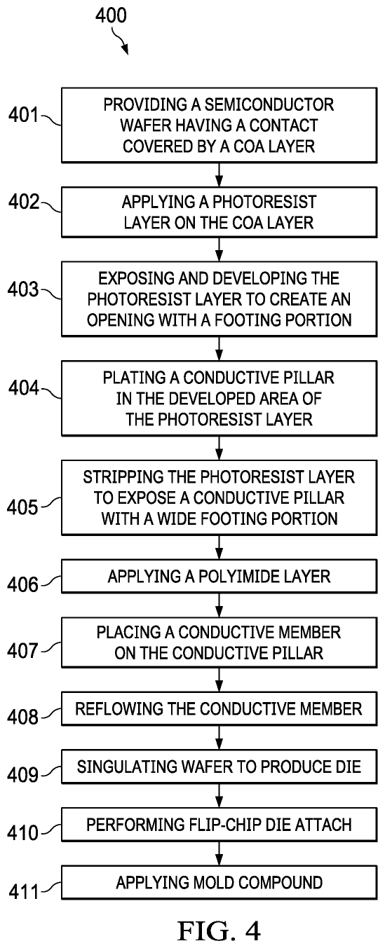

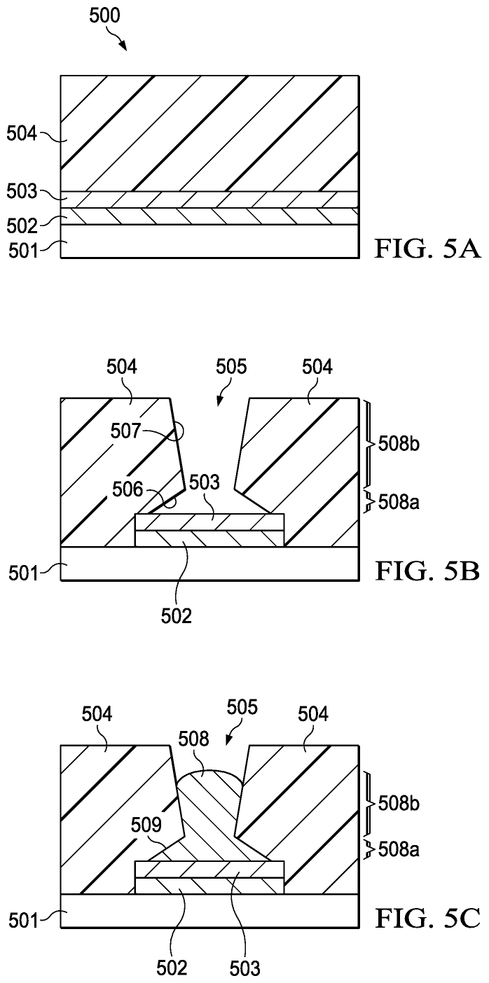

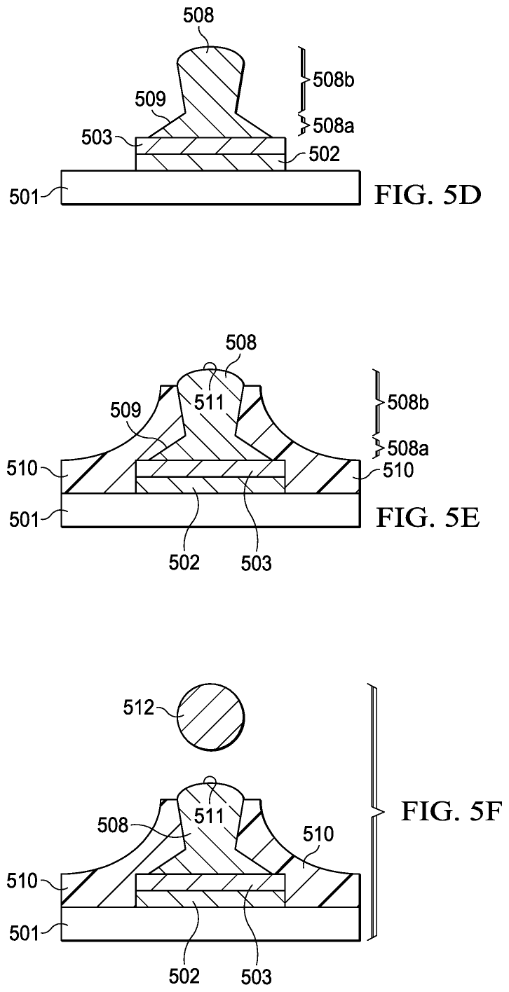

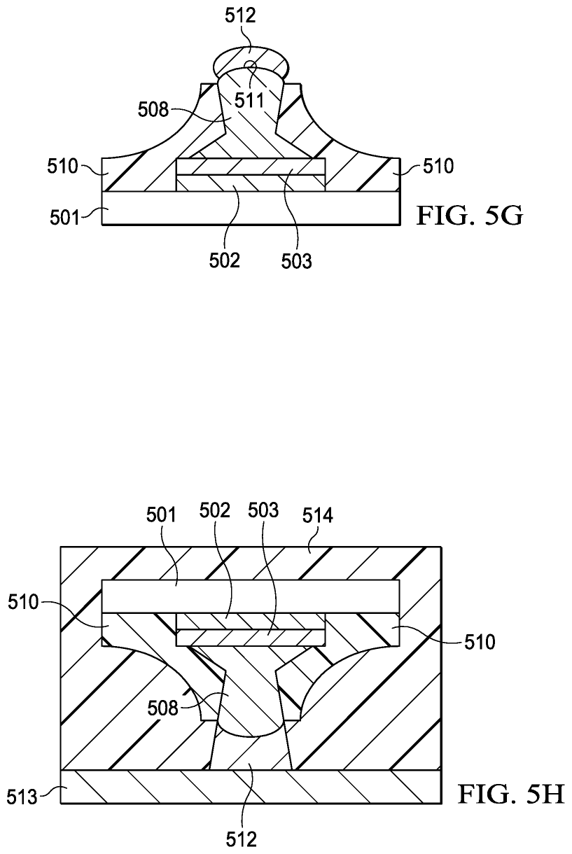

FIG. 2 is a flow diagram illustrating the major steps of a method 200 for forming pillar bumps having an unobstructed solder interfacial area according to an example semiconductor package. FIGS. 3A-H are a series of cross-sectional views illustrating the steps in the formation of the pillar bumps using the process of FIG. 2.

Steps 201 and 202 are illustrated in FIG. 3A, which shows a small portion of a semiconductor die 300. It will be understood that semiconductor die 300 may extend to the left and to the right to include various circuitry and multiple contact regions. Semiconductor die 300 comprises a semiconductor wafer 301, such as a silicon wafer. A contact region 302 has been formed on a device side of the semiconductor wafer 301. A COA layer 303 has been deposited to form a metal feature that is in contact with contact region 302. The contact region 302 may be a seed layer for contact to COA layer 303. The COA layer 303 may be applied by sputtering, for example. A photoresist layer 304 is applied over COA layer 303. The photoresist 304 may be a positive or negative photoresist.

The method 200 further comprises exposing and developing the photoresist layer to create an orifice 305. In one example, as illustrated in FIG. 3B, orifice 305 may be sloped or funnel shaped. In other examples, orifice 305 may have relatively straight vertical sides. As FIG. 3B shows, the photoresist layer 304 has been patterned, exposed, and developed to define orifice 305. A top region 305a of orifice 305 may be wider near the upper surface 306 of the photoresist layer 304 than a bottom region 305b of orifice 305 near the COA layer 303.

The method 200 further comprises plating a conductive pillar in the developed area of the photoresist layer 204. For example, as shown in FIG. 3C, a conductive pillar 307 is formed in orifice 305 using a plating technique, such as electroplating or electro-less plating. As used herein, the term “conductive pillar” refers to a refers to a conductive pathway or via that provides an electrical connection between a semiconductor wafer or integrated circuit die and other components. The conductive pillar may also be referred to as a post or bump and may be formed by copper, solder, or other interconnect structure. No limitation to any particular structure of the conductive pillar is intended or should be implied. The plating operation fills opening 305 in photoresist 304 with material to form a pillar 307. Conductive pillar 307 has a base portion 308 that is formed in orifice 305 and a top portion 309 that is formed above the upper surface 306 of photoresist 304. The top portion 309 may be created by overplating, which results in pillar 307 having mushroom-like shape. As used herein, the term “mushroom-like shape” refers to a generally vertical structure having distinct top and bottom portions such that a radius of the top portion is larger than a radius of the bottom portion. In some examples, the sidewalls of the top and bottom portions may be sloped or curved in which cases average, median, or maximum radii of the top portion and bottom portion may be compared to identify the top portion has larger than the bottom portion. In some examples, the top and bottom portions of the structure are formed from a single material and/or during a same process. An edge or lip 309a of the top portion 309 overlaps photoresist 304 and extends away from the base portion 308. The relative radius of the base portion 308 to the radius of top portion 309 and, therefore, the length of lip 309a is dependent upon the amount of overplating performed and may vary as a design choice. In one example, the top surface 310 of pillar 307 has a curved or domed shape as a result of the overplating. The length of lip 309 and the curvature of top surface may be selected as a design choice based upon the materials used to form the conductive pillar 307, photoresist layer 304, and PI layer 311 to minimize the amount of PI layer 311 that covers top surface 310.

The method 200 further comprises stripping the photoresist layer 205 to expose a mushroom-shaped conductive pillar with a domed top surface. As shown in FIG. 3D, the photoresist layer 304 has been removed to leave conductive pillar 307 attached to COA layer 303. In one example, a wet cleaning process is used to strip and etch the photoresist layer 304. The method 200 further comprises applying a PI layer 206. As shown in FIG. 3E, PI layer 311 has been applied to the semiconductor wafer 301 and COA layer 303. The PI layer 311 is applied throughout the device and is patterned so that the PI layer is removed from the top surface 310 of the conductive pillar 307. The PI layer 311 surrounds the base portion 308 of pillar 307 and may include a region 311a of PI that is built up around the pillar 307. The dome shape of top surface 310 on pillar 307 causes the PI layer 311 to flow off pillar 307. As a result, more surface area is exposed on the top surface 310 than on existing pillar designs.

The method 200 comprises placing (e.g., dropping) a conductive member on the conductive pillar 207. For example, in FIG. 3F, a conductive member 312 (e.g., solder) is positioned on the top surface 310 of conductive pillar 307. In some configurations, a flux adhesive material may be applied to top surface 310 prior to placing the conductive member 312 on pillar 307. In some instances, the conductive member 312 is a solder ball that is placed using a stencil and brush technique or using a cyclone technique. In some examples, the conductive member 312 is a spherical conductive material. In some examples, the conductive member 312 is a different shape than a sphere, e.g., a rectangular prism, another type of prism, or any other suitable shape. The conductive member 312 in these instances may be sized as appropriate. The method 200 further comprises reflowing the conductive member 208. FIG. 3G depicts the conductive member 312 having been reflowed. The dome-shaped top surface 310 creates a lower tendency for the PI layer 311 to stay on the surface of pillar 307. When compared to existing designs, this increases the interfacial area between pillar 307 and the reflowed conductive member 312 and increases the wettable surface area of conductive member 312 during reflow.

The method 200 then comprises singulating the wafer (e.g., using a sawing technique) to produce a die 209 that includes the structures depicted in FIG. 3G. The method 200 further comprises flipping and attaching the structure of FIG. 3G to a conductive terminal 210. FIG. 3H depicts the structure of FIG. 3G flipped upside down and attached to a conductive terminal 313, which may be part of a lead frame. The attachment may be achieved, for example, by reflowing the conductive member to form a conductive layer 312, such as a solder layer. The method 200 also comprises applying a mold compound 211, such as epoxy or other encapsulant. As depicted in FIG. 3H, mold compound 314 covers the conductive terminal 313, semiconductor wafer 301, conductive pillar 307, conductive member 312, and the other structures.

FIG. 4 is a flow diagram illustrating the major steps of an alternative method 400 for forming pillar bumps having an unobstructed solder interfacial area according to one embodiment. FIGS. 5A-H are a series of cross-sectional views illustrating the steps in the formation of the pillar bumps using the process of FIG. 4.

Steps 401 and 402 are illustrated in FIG. 5A, which shows a small portion of a semiconductor die 500. It will be understood that die 500 may extend to the left and to the right to include various circuitry and multiple contact regions. Semiconductor die 500 comprises a semiconductor wafer 501, such as a silicon wafer. A contact region 502 has been formed on a device side of semiconductor wafer 501. A COA layer 503 has been deposited to form a metal feature that is in contact with contact region 502. For example, the contact region 502 may be a seed layer for contact to COA layer 503. The COA layer 503 may be applied by sputtering, for example. A photoresist layer 504 is applied over COA layer 503. The photoresist 504 may be a positive or negative photoresist.

The method 400 further comprises exposing and developing the photoresist layer to create an opening 505. As FIG. 5B shows, the photoresist layer 504 has been patterned, exposed, and developed to define opening 505. A bottom or footing region 505a of opening 505 is formed above COA layer 503. The footing region 505a is wider than an upper region 505b of opening 505. The footing region 505a has sloped sidewalls 506 that extend from COA layer 503 to sidewalls 507 of the upper region 505b. In some examples, the sidewalls 506 of footing region 505a extend less than half the height of opening 505 so that footing region 505a is shorter than upper region 505b. The sidewalls 507 of upper region 505b may be sloped outwardly as shown in FIG. 5B. In other examples, the sidewalls 507 of the upper region may have a generally vertical orientation. The relative width of the footing region 505a to upper region 505b may vary as a design choice.

The method 400 further comprises plating a conductive pillar in the developed area of the photoresist layer 404. For example, as shown in FIG. 5C, a conductive pillar 508 is formed in opening 505 using a plating technique, such as electroplating or electro-less plating. The plating operation fills openings 505 in photoresist 504 with material to form a pillar 508. In some examples, the conductive pillar 508 is manufactured using copper. Conductive pillar 508 has a footing portion 508a that is formed in footing region 505a of opening 505 and a top portion 508b that is formed in the upper region 505b of opening 505. Footing portion 508a and upper portion 508b take the shape of footing region 505a and upper region 505b, respectively. Footing region 508a has a sloped surface 509 that extends away from upper region 505b to COA layer 503.

The method 400 further comprises stripping the photoresist layer 405 to expose a conductive pillar with a wide footing portion. As shown in FIG. 5D, the photoresist layer 504 has been removed to leave conductive pillar 508 attached to COA layer 503. In one example, a wet cleaning process is used to strip and etch the photoresist layer 504. The method 400 further comprises applying a PI layer 406. As shown in FIG. 5E, PI layer 510 has been applied to the semiconductor wafer 501 and to COA layer 503. The PI layer 510 is applied throughout the device and is patterned so that the PI layer is removed from the top surface 511 of the conductive pillar 508. While the PI layer 510 is being applied, the sloped surface 509 of footing portion 508a prevents the PI layer 510 from flowing over the top surface 511 of conductive pillar 508. As a result, more surface area is exposed on the top surface 511 than on existing pillar designs.

The method 400 comprises placing (e.g., dropping) a conductive member on the conductive pillar 407. For example, in FIG. 5F, a conductive member 512 (e.g., solder) is positioned on the top surface 511 of conductive pillar 508. In some configurations, a flux adhesive material may be applied to top surface 511 prior to placing the conductive member 512 on pillar 508. In some instances, the conductive member 512 is a solder ball that is placed using a stencil and brush technique or using a cyclone technique. In some examples, the conductive member 512 is a spherical conductive material. In some examples, the conductive member 512 is a different shape than a sphere, e.g., a rectangular prism, another type of prism, or any other suitable shape. The conductive member 512 in these instances may be sized as appropriate. The method 400 further comprises reflowing the conductive member 408. FIG. 5G depicts the conductive member 512 having been reflowed. The footing portion 508a creates a lower tendency for the PI layer 510 to cover the surface 511 of pillar 508, which increases the interfacial area between pillar 508 and the reflowed conductive member 512 and increases the wettable surface area of conductive member 512 during reflow.

The method 400 then comprises singulating the wafer (e.g., using a sawing technique) to produce a die 409 that includes the structures depicted in FIG. 5G. The method 400 further comprises flipping and attaching the structure of FIG. 5G to a conductive terminal 410. For example, FIG. 5H depicts the structure of FIG. 5G flipped upside down and attached (e.g., by reflowing the conductive member to form a conductive layer 512, such as a solder layer, to a conductive terminal 513, which may be part of a lead frame. The method 400 also comprises applying a mold compound, such as epoxy or other encapsulant, 411. As depicted in FIG. 5H, mold compound 514 covers the conductive terminal 503, semiconductor wafer 501, conductive pillar 508, conductive member (solder) 512, and the other structures.

An example semiconductor package includes a semiconductor die having a device side with a conductive layer coupled to the device side. A conductive pillar is coupled to the conductive layer. The conductive pillar has an upper portion and a base portion. The upper portion has a wider diameter than the base portion so that a lip on the underside of the upper portion extends away from the base portion. A polyimide layer is coupled to the conductive layer and surrounds the conductive pillar. A solder layer is coupled to the conductive pillar. The polyimide layer does not extend between a top surface of the conductive pillar and the solder layer. A conductive terminal, such as a lead frame, is coupled to the solder layer and is exposed to a surface of the semiconductor package. The device side of the semiconductor die faces the conductive terminal. The conductive pillar may be copper. The conductive pillar may have a mushroom shape. The top surface of the conductive pillar may have a convex or domed shape. The upper portion of the conductive pillar extends farther away from the device side of the semiconductor die than does the polyimide layer.

Another example semiconductor package includes a semiconductor die having a device side. A conductive layer is coupled to the device side. A conductive pillar is coupled to the conductive layer. The conductive pillar has an upper portion and a base portion. The base portion has a wider diameter than the upper portion. A polyimide layer is coupled to the conductive layer and surrounds the conductive pillar. A solder layer is coupled to the conductive pillar. The polyimide layer does not extend between a top surface of the conductive pillar and the solder layer. A conductive terminal, such as a lead frame, is coupled to the solder layer and is exposed to a surface of the semiconductor package. The device side of the semiconductor die faces the conductive terminal. The conductive pillar may be copper. The base portion of the conductive pillar may have sloped sides that extend from the upper portion to the conductive layer. The top surface of the conductive pillar may have a convex or domed shape. The upper surface of the conductive pillar extends farther away from the device side of the semiconductor die than does the polyimide layer.

An example method of manufacturing a semiconductor package includes the steps of providing a semiconductor wafer having a device side, forming a conductive layer above the device side, forming a conductive pillar above the conductive layer, the conductive pillar having a base portion and an upper portion, wherein one of the base or upper portions is wider than the other portion. The example method further includes forming a polyimide layer abutting the conductive layer and surrounding the conductive pillar, positioning a conductive member on the conductive pillar, wherein the polyimide layer does not extend between a top surface of the conductive pillar and the conductive member. The example method further includes reflowing the conductive member, singulating the semiconductor wafer to produce a die having the conductive layer, the conductive pillar, the polyimide layer, and the reflowed conductive member, coupling the reflowed conductive member to a conductive terminal using a reflow technique, thereby producing a solder layer coupling the conductive pillar to the conductive terminal, and covering the die, the conductive pillar, the solder layer, and the conductive terminal in a molding, the conductive terminal exposed to a surface of the molding. The conductive member may be copper. The upper portion of the conductive pillar may a wider diameter than the base portion in one example such that the conductive pillar has a mushroom shape. The base portion of the conductive pillar may have a wider diameter than the upper portion in another example, and sloped sides on the base portion may extend from the upper portion to the conductive layer. Forming the polyimide layer may include preventing the polyimide layer from extending over the top surface of the conductive pillar due to the shape of the upper portion of the conductive pillar. Alternatively, forming the polyimide layer may include preventing the polyimide layer from extending over the top surface of the conductive pillar due to the shape of the lower portion of the conductive pillar.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A semiconductor package, comprising:
a semiconductor die having a device side;
a conductive layer coupled to the device side;
a conductive pillar coupled to the conductive layer, the conductive pillar having an upper portion and a base portion, the upper portion having a wider diameter than the base portion;
a polyimide layer coupled to the conductive layer and surrounding the conductive pillar;
a solder layer coupled to the conductive pillar, wherein the polyimide layer does not extend between a top surface of the conductive pillar and the solder layer; and
a conductive terminal coupled to the solder layer and exposed to a surface of the semiconductor package, the device side of the semiconductor die facing the conductive terminal.

2. The semiconductor package of claim 1, wherein the conductive pillar comprises copper.

3. The semiconductor package of claim 1, wherein the conductive pillar has a mushroom shape.

4. The semiconductor package of claim 1, wherein the top surface of the conductive pillar has a convex shape.

5. The semiconductor package of claim 1, wherein the upper portion of the conductive pillar extends farther away from the device side of the semiconductor die than does the polyimide layer.

6. The semiconductor package of claim 1, wherein the conductive terminal is a portion of a lead frame.

7. A semiconductor package, comprising:
a semiconductor die having a device side;
a conductive layer coupled to the device side;
a conductive pillar coupled to the conductive layer, the conductive pillar having an upper portion and a base portion, the base portion having a wider diameter than the upper portion;
a polyimide layer coupled to the conductive layer and surrounding the conductive pillar;
a solder layer coupled to the conductive pillar, wherein the polyimide layer does not extend between a top surface of the conductive pillar and the solder layer; and
a conductive terminal coupled to the solder layer and exposed to a surface of the semiconductor package, the device side of the semiconductor die facing the conductive terminal.

8. The semiconductor package of claim 7, wherein the conductive pillar comprises copper.

9. The semiconductor package of claim 7, wherein the base portion of the conductive pillar has sloped sides extending from the upper portion to the conductive layer.

10. The semiconductor package of claim 7, wherein the top surface of the conductive pillar has a convex shape.

11. The semiconductor package of claim 7, wherein the upper surface of the conductive pillar extends farther away from the device side of the semiconductor die than does the polyimide layer.

12. The semiconductor package of claim 7, wherein the conductive terminal is a portion of a lead frame.

13. A method of manufacturing a semiconductor package, comprising:
providing a semiconductor wafer having a device side;
forming a conductive layer above the device side;
forming a conductive pillar above the conductive layer, the conductive pillar having a base portion and an upper portion, wherein one of the base or upper portions is wider than the other portion;
forming a polyimide layer abutting the conductive layer and surrounding the conductive pillar;
positioning a conductive member on the conductive pillar, wherein the polyimide layer does not extend between a top surface of the conductive pillar and the conductive member;
reflowing the conductive member;
singulating the semiconductor wafer to produce a die having the conductive layer, the conductive pillar, the polyimide layer, and the reflowed conductive member;
coupling the reflowed conductive member to a conductive terminal using a reflow technique, thereby producing a solder layer coupling the conductive pillar to the conductive terminal; and
covering the die, the conductive pillar, the solder layer, and the conductive terminal in a molding, the conductive terminal exposed to a surface of the molding.

14. The method of claim 13, wherein the conductive member comprises copper.

15. The method of claim 13, wherein the upper portion having a wider diameter than the base portion.

16. The method of claim 15, wherein the conductive pillar has a mushroom shape.

17. The method of claim 13, wherein the base portion having a wider diameter than the upper portion.

18. The method of claim 17, wherein the base portion of the conductive pillar has sloped sides extending from the upper portion to the conductive layer.

19. The method of claim 13, wherein forming the polyimide layer comprises preventing the polyimide layer from extending over the top surface of the conductive pillar due to the shape of the upper portion of the conductive pillar.

20. The method of claim 13, wherein forming the polyimide layer comprises preventing the polyimide layer from extending over the top surface of the conductive pillar due to the shape of the lower portion of the conductive pillar.
